(19) United States
(12) Patent Application Publication
(10) Pub. No.: US 2025/0380439 A1
(43) Pub. Date: Dec. 11, 2025

(54) SEMICONDUCTOR DEVICE

(71) Applicant: FUJI ELECTRIC CO., LTD., Kanagawa (JP)

(72) Inventors: Yoshihiro IKURA, Matsumoto-city (JP); Tatsuya NAITO, Matsumoto-city (JP); Masahiro SASAKI, Azumino-city (JP); Norihiro KOMIYAMA, Matsumoto-city (JP); Hui ZHANG, Tokyo (JP)

(21) Appl. No.: 19/308,276

(22) Filed: Aug. 24, 2025

Related U.S. Application Data
(63) Continuation of application No. PCT/JP2024/027790, filed on Aug. 2, 2024.

(30) Foreign Application Priority Data
Sep. 12, 2023 (JP) 2023-147729

(51) Int. Cl. H10D 12/00; H10D 62/10; H10D 62/53; H10D 62/60

(52) U.S. Cl. CPC H10D 12/481; H10D 62/108; H10D 62/126; H10D 62/53; H10D 62/60

(57) ABSTRACT

Provided is a semiconductor device including: trench portions arrayed in a predetermined array direction on a front surface side of a semiconductor substrate, having a repetitive structure in which a gate trench portion and a dummy trench portion are repeated; a first conductivity type drift region provided in the semiconductor substrate; a second conductivity type base region provided above the drift region; a first conductivity type emitter region provided above the base region, having a higher doping concentration than the drift region; a second conductivity type contact region provided above the base region, having a higher doping concentration than the base region; and a second conductivity type trench bottom region provided below the gate trench portion, having a doping concentration lower than that of the base region, wherein the trench bottom region is provided below the emitter region, and a length thereof is shorter than that of the repetitive structure.

The contents of the following patent application(s) are incorporated herein by reference:
NO. 2023-147729 filed in JP on Sep. 12, 2023
NO. PCT/JP2024/027790 filed in WO on Aug. 2, 2024.

### BACKGROUND

### 1. Technical Field

The present invention relates to a semiconductor device.

### 2. Related Art

Patent Document 1 describes an “IGBT having dV/dt controllability”.

### RELATED ART DOCUMENTS

### Patent Documents

Patent Document 1: Japanese Patent Application Publication No. 2019-91892
Patent Document 2: Japanese Patent Application Publication No. 2004-6647
Patent Document 3: Japanese Patent Application Publication No. 2015-195307
Patent Document 4: Japanese Patent Application Publication No. 2019-110288
Patent Document 5: International Publication No. WO2022/158053
Patent Document 6: Japanese Patent No. 6472714

### BRIEF DESCRIPTION OF THE DRAWINGS

FIG. 1 illustrates an example of an upper surface of a semiconductor device 100.

FIG. 2A illustrates an example of a region R in FIG. 1.

FIG. 2B illustrates an example of a cross section a-a′ in FIG. 2A.

FIG. 3 illustrates the region R in a modification of the semiconductor device 100.

FIG. 4A illustrates the region R in a modification of the semiconductor device 100.

FIG. 4B illustrates an example of a cross section b-b′ in FIG. 4A.

FIG. 5 illustrates the region R in a modification of the semiconductor device 100.

FIG. 6A illustrates the region R in a modification of the semiconductor device 100.

FIG. 6B illustrates an example of a cross section c-c′ in FIG. 6A.

FIG. 7 illustrates the region R in a modification of the semiconductor device 100.

FIG. 8A illustrates the region R in a modification of the semiconductor device 100.

FIG. 8B illustrates an example of a cross section d-d′ in FIG. 8A.

### DESCRIPTION OF EXEMPLARY EMBODIMENTS

Hereinafter, the invention will be described through embodiments of the invention, but the following embodiments do not limit the invention according to claims. In addition, not all of the combinations of features described in the embodiments are essential to the solving means of the invention.

In the present specification, one side in a direction parallel to a depth direction of a semiconductor substrate is referred to as “upper” and another side is referred to as “lower”. One surface of two principal surfaces of a substrate, a layer or other member is referred to as an upper surface, and another surface is referred to as a lower surface. “Upper” and “lower” directions are not limited to a direction of gravity, or a direction in which a semiconductor device is mounted.

In the present specification, technical matters may be described using orthogonal coordinate axes of an X axis, a Y axis, and a Z axis. The orthogonal coordinate axes merely specify relative positions of components, and do not limit a specific direction. For example, the Z axis is not limited to indicate the height direction with respect to the ground. Note that a +Z axis direction and a −Z axis direction are directions opposite to each other. When a Z axis direction is described without describing the signs, it means that the direction is parallel to a +Z axis and a −Z axis.

In the present specification, orthogonal axes parallel to the upper surface and the lower surface of the semiconductor substrate are referred to as the X axis and the Y axis. Further, an axis perpendicular to the upper surface and the lower surface of the semiconductor substrate is referred to as the Z axis. In the present specification, the direction of the Z axis may be referred to as the depth direction. Further, in the present specification, a direction parallel to the upper surface and the lower surface of the semiconductor substrate may be referred to as a horizontal direction, including an X axis direction and a Y axis direction.

In the present specification, a case where a term such as “same” or “equal” is mentioned may include a case where an error due to a variation in manufacturing or the like is included. The error is, for example, within 10%.

In the present specification, a conductivity type of doping region where doping has been carried out with an impurity is described as a P type or an N type. In the present specification, the impurity may particularly mean either a donor of the N type or an acceptor of the P type, and may be described as a dopant. In the present specification, doping means introducing the donor or the acceptor into the semiconductor substrate and turning it into a semiconductor presenting a conductivity type of the N type, or a semiconductor presenting a conductivity type of the P type.

In the present specification, a doping concentration means a concentration of the donor or a concentration of the acceptor in a thermal equilibrium state. In the present specification, a net doping concentration means a net concentration obtained by adding the donor concentration set as a positive ion concentration to the acceptor concentration set as a negative ion concentration, taking into account of polarities of charges. As an example, when the donor concentration is ND and the acceptor concentration is N_{A}, the net doping concentration at any position is given as ND-N_{A}. In the present specification, the net doping concentration may be simply referred to as the doping concentration.

In the present specification, a description of a P+ type or an N+ type means a higher doping concentration than that of the P type or the N type, and a description of a P− type or an N− type means a lower doping concentration than that of the P type or the N type. In addition, in the present specification, a description of a P++ type or an N++ type means a higher doping concentration than that of the P+ type or the N+ type, and a description of a P−− type or an N−− type means a higher doping concentration than that of the P− type or the N− type.

When a concentration distribution of the donor, acceptor, or net doping has a peak in a region, a value of the peak may be set as the concentration of the donor, acceptor, or net doping in the region. In a case where the concentration of the donor, acceptor or net doping is substantially uniform in a region, or the like, an average value of the concentration of the donor, acceptor or net doping in the region may be set as the concentration of the donor, acceptor or net doping.

In each example, an example is illustrated in which the first conductivity type is the N type and the second conductivity type is the P type, but the first conductivity type may be the P type and the second conductivity type may be the N type. In this case, the conductivity types of the substrate, the layer, the region, and the like in each example have opposite polarities.

The present specification employs SI unit system. In the present specification, a unit of a distance or length may be represented by centimeter (cm). In this case, various calculations may be converted into m (meter) to be calculated. As for numeric representation of power of 10, for example, the representation 1E+16 indicates 1×10¹⁶, and the representation 1E-16 indicates 1×10⁻¹⁶.

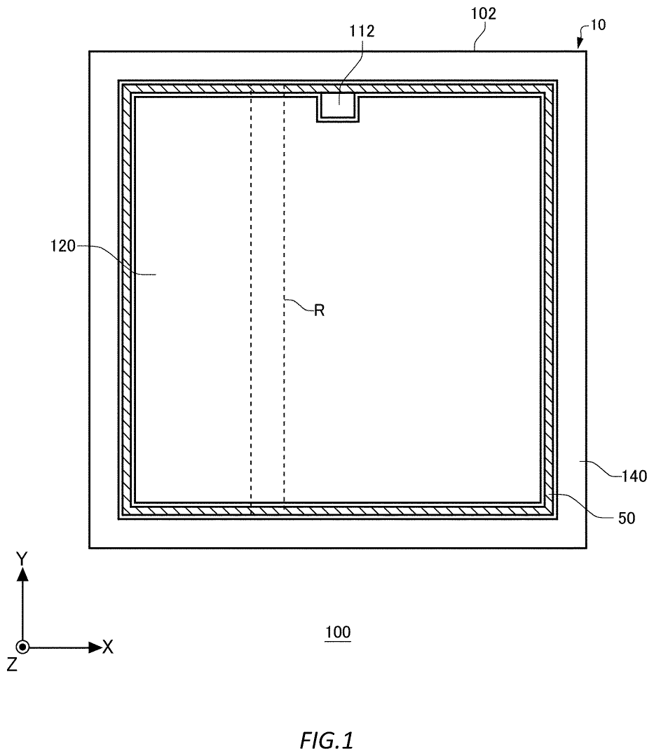

FIG. 1 illustrates an example of an upper surface of a semiconductor device 100. The semiconductor device 100 in the present example includes a gate runner portion 50, a gate pad 112, an active portion 120, and an edge termination structure portion 140.

The semiconductor substrate 10 is a substrate that is formed of a semiconductor material. The semiconductor substrate 10 may be a silicon substrate or a silicon carbide substrate. The semiconductor substrate 10 in the present example is a silicon substrate. Note that when merely referred to as a top view in the present specification, it means that the semiconductor substrate 10 is viewed from an upper surface side. The semiconductor substrate 10 has an end side 102. In addition, the semiconductor substrate 10 has a front surface 21 and a back surface 23 as described later.

The active portion 120 is a region through which a main current flows in the depth direction between the front surface 21 and the back surface 23 of the semiconductor substrate 10 when the semiconductor device 100 operates. An emitter electrode 52 is provided above the active portion 120, but illustration thereof is omitted in this drawing.

The gate pad 112 is provided above the semiconductor substrate 10. A gate potential is applied to the gate pad 112. The gate pad 112 is electrically connected to the gate trench portion 40 of the active portion 120. The gate trench portion 40 will be described later.

The gate runner portion 50 is provided on the end side 102 side of the semiconductor substrate 10 with respect to the active portion 120 in top view. The gate runner portion 50 connects the gate pad 112 and the gate trench portion 40.

The edge termination structure portion 140 is provided at the front surface 21 of the semiconductor substrate 10. The edge termination structure portion 140 is provided on the end side 102 side of the semiconductor substrate 10 with respect to the gate runner portion 50 in top view. The edge termination structure portion 140 reduces electric field strength on the front surface 21 side of the semiconductor substrate 10. The edge termination structure portion 140 may include at least one of a guard ring, a field plate, or a RESURF which is annularly provided to enclose the active portion 120.

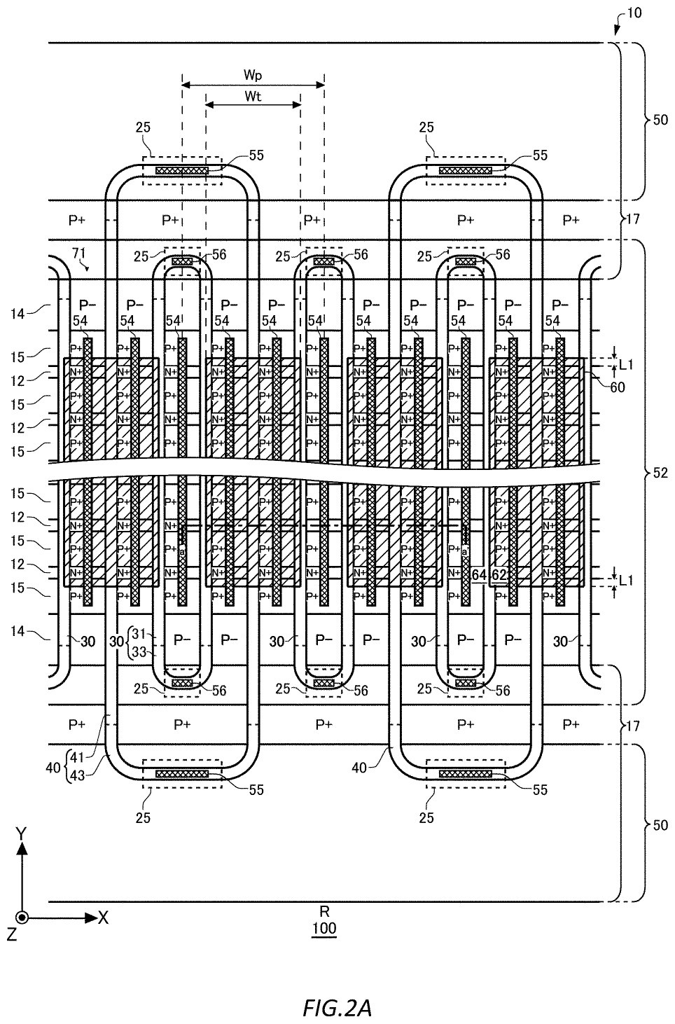

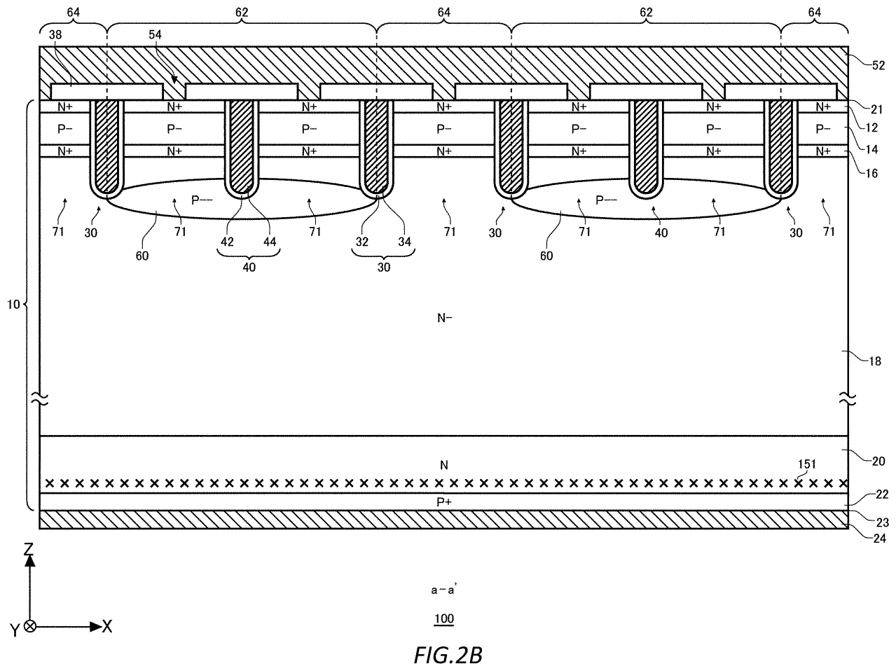

FIG. 2A illustrates an example of a region R in FIG. 1. The semiconductor device 100 may be configured by repeatedly arranging a configuration illustrated in this drawing in positive and negative directions of the X axis. However, as illustrated in FIG. 1, the gate runner portion 50 and the edge termination structure portion 140 may be provided at end portions in the positive and negative directions of the X axis.

The semiconductor device 100 may include a transistor such as an IGBT. In the present example, the semiconductor device 100 is an IGBT. Note that the semiconductor device 100 may be a reverse blocking type or reverse conducting type IGBT, or may be another transistor such as a MOSFET.

The semiconductor device 100 in the present example includes a dummy trench portion 30, the gate trench portion 40, the gate runner portion 50, an emitter region 12, a base region 14, a contact region 15, and a well region 17 at the front surface 21 of a semiconductor substrate 10. The semiconductor device 100 in the present example includes the emitter electrode 52 provided above the front surface 21 of the semiconductor substrate 10. In addition, the semiconductor device 100 in the present example includes a trench bottom region 60 provided below the gate trench portion 40. Although the trench bottom region 60 is a region which is not exposed to the front surface 21 of the semiconductor substrate 10, in this drawing, a region where the trench bottom region 60 is provided is indicated by hatching in top view.

The emitter electrode 52 and the gate runner portion 50 are provided above the semiconductor substrate 10 with an interlayer dielectric film 38 interposed therebetween. Illustration of the interlayer dielectric film 38 is omitted in FIG. 2A. A contact hole 54, a contact hole 55, and a contact hole 56 are provided to penetrate the interlayer dielectric film 38. The emitter electrode 52 is provided above the gate trench portion 40, the dummy trench portion 30, the emitter region 12, the base region 14, the contact region 15, and the well region 17. In addition, the gate runner portion 50 is provided above the well region 17.

The emitter electrode 52 and the gate runner portion 50 are formed of a material containing metal. At least a partial region of the emitter electrode 52 may be formed of metal such as aluminum (Al) or of a metal alloy such as an aluminum-silicon alloy (AlSi) or an aluminum-silicon-copper alloy (AlSiCu). At least a partial region of the gate runner portion 50 may be formed of metal such as aluminum (Al) or of a metal alloy such as an aluminum-silicon alloy (AlSi) or an aluminum-silicon-copper alloy (AlSiCu). The emitter electrode 52 and the gate runner portion 50 may include a barrier metal layer formed of titanium, a titanium compound, or the like under the region formed of aluminum or the like. The emitter electrode 52 and the gate runner portion 50 are provided separately from each other.

In the active portion 120, the contact hole 54 is formed above each region of the emitter region 12 and the contact region 15. The contact hole 54 is not provided above the well regions 17 provided at both ends in the Y axis direction. In this manner, one or more contact holes 54 are formed in the interlayer dielectric film 38. The one or more contact holes 54 may be provided extending in an extending direction of a plurality of trench portions.

The contact hole 55 electrically connects the gate runner portion 50 and a gate conductive portion in the active portion 120 via a connection portion 25. A plug layer formed of tungsten or the like may be formed inside the contact hole 55.

The contact hole 56 connects the emitter electrode 52 and a dummy conductive portion in the dummy trench portion 30 via the connection portion 25. A plug layer formed of tungsten or the like may be formed inside the contact hole 56.

The connection portion 25 is connected to the emitter electrode 52 or the gate runner portion 50. In an example, the connection portion 25 is provided between the gate runner portion 50 and the gate conductive portion. The connection portion 25 in the present example may be provided extending in the X axis direction and electrically connected to the gate conductive portion. The connection portion 25 may also be provided between the emitter electrode 52 and the dummy conductive portion. The connection portion 25 is a conductive material such as polysilicon doped with impurities. The connection portion 25 in the present example is polysilicon (N+) doped with impurities of the N type. The connection portion 25 is provided above the front surface 21 of the semiconductor substrate 10 via a dielectric film such as an oxide film, or the like.

The dummy trench portion 30 is provided on the front surface 21 side of the semiconductor substrate 10. The dummy trench portions 30 are arrayed in a predetermined array direction (X axis direction in the present example) on the front surface 21 side of the semiconductor substrate 10. The dummy trench portion 30 is a trench portion electrically connected to the emitter electrode 52. The dummy trench portion 30 may have two extending parts 31 extending along the extending direction (the Y axis direction in the present example) which is parallel to the front surface 21 of the semiconductor substrate 10 and is perpendicular to the array direction, and a connecting part 33 which connects the two extending parts 31.

At least a part of the connecting part 33 is preferably formed in a curved shape. Connecting the end portions of two extending parts 31 of the dummy trench portion 30 can reduce the electric field strength at the end portions of the extending parts 31.

The gate trench portion 40 is provided on the front surface 21 side of the semiconductor substrate 10. The gate trench portions 40 are arrayed in a predetermined array direction (the X axis direction in the present example) on the front surface 21 side of the semiconductor substrate 10. The gate trench portion 40 may have two extending parts 41 extending along the extending direction (the Y axis direction in the present example) which is parallel to the front surface 21 of the semiconductor substrate 10 and is perpendicular to the array direction, and a connecting part 43 which connects the two extending parts 41.

At least a part of the connecting part 43 is preferably formed in a curved shape. Connecting the end portions of two extending parts 41 of the gate trench portion 40 can reduce the electric field strength at the end portions of the extending parts 41.

The semiconductor device 100 in the present example includes a plurality of trench portions arrayed in a predetermined array direction (the X axis direction in the present example) on the front surface 21 side of the semiconductor substrate 10. The plurality of trench portions have a repetitive structure in which the gate trench portion 40 and the dummy trench portion 30 are repeated at a predetermined cycle in the array direction.

The plurality of trench portions in the present example has a repetitive structure in which the dummy trench portion 30, the gate trench portion 40, and the dummy trench portion 30 are repeated in this order in the array direction (the X axis direction in the present example). That is, the semiconductor device 100 in the present example includes the gate trench portions 40 and the dummy trench portions 30 at a ratio of 1:2.

However, the ratio between the gate trench portion 40 and the dummy trench portion 30 is not limited to the present example. A proportion of the gate trench portions 40 may be greater than a proportion of the dummy trench portions 30, or the proportion of the dummy trench portions 30 may be the same as the proportion of the gate trench portions 40. The ratio between the gate trench portion 40 and the dummy trench portion 30 may be 1:1, 1:5, or 3:2.

Note that the cycle of the repetitive structure included in the plurality of trench portions may be determined based on repetition of the extending part 41 of the gate trench portion 40 and the extending part 31 of the dummy trench portion 30. For example, the semiconductor device 100 in the present example has a repetitive structure consisting of the gate trench portion 40 having a loop shape, the dummy trench portion 30 having a loop shape and surrounded by the gate trench portion 40 having a loop shape, and the dummy trench portion 30 having a loop shape and not surrounded by the gate trench portion 40 having a loop shape, and has a cycle composed of six extending parts. On the other hand, focusing only on the extending part, the semiconductor device 100 has a repetitive structure in which the dummy trench portion 30, the gate trench portion 40, and the dummy trench portion 30 are repeated in this order, and has a cycle composed of three extending parts.

As described above, the cycle of the repetitive structure included in the plurality of trench portions may be a minimum cycle of the repetitive structure included in the extending parts of the plurality of trench portions. That is, a length of the repetitive structure included in the plurality of trench portions in the present example is a length Wp illustrated in the drawing.

A mesa portion 71 is a mesa portion provided adjacent to the trench portion in a plane parallel to the front surface 21 of the semiconductor substrate 10. The mesa portion may be a part of the semiconductor substrate 10 sandwiched between two trench portions adjacent to each other, and may be a part from the front surface 21 of the semiconductor substrate 10 to a depth of a lowermost bottom portion of each trench portion.

The mesa portion 71 is provided adjacent to at least one of the dummy trench portion 30 or the gate trench portion 40 in the active portion 120. The mesa portion 71 has the emitter region 12, the base region 14, the contact region 15, and the well region 17 at the front surface 21 of the semiconductor substrate 10.

The base region 14 is a region of the second conductivity type provided above a drift region 18 described later. The base region 14 in the present example is of the P− type as an example.

The emitter region 12 is a region of the first conductivity type which is provided above the base region 14 and has a doping concentration higher than that of the drift region 18. The emitter region 12 in the present example is of the N+ type as an example. Examples of a dopant of the emitter region 12 include arsenic (As). The emitter region 12 is provided in contact with the gate trench portion 40 at the front surface 21. The emitter region 12 may be provided extending in the X axis direction from one of the two trench portions to another. The emitter region 12 is also provided below the contact hole 54. A part of the emitter region 12 exposed below the contact hole 54 may be provided with a high-concentration portion having a doping concentration higher than those of other parts.

In addition, the emitter region 12 may or may not be in contact with the dummy trench portion 30. The emitter region 12 in the present example is in contact with the dummy trench portion 30.

The contact region 15 is a region of the second conductivity type which is provided above the base region 14 and has a doping concentration higher than that of the base region 14. The contact region 15 in the present example is of the P+ type as an example. The contact region 15 in the present example is provided at the front surface 21. The contact region 15 may be provided in the X axis direction from one of the two trench portions to another. The contact region 15 may or may not be in contact with the gate trench portion 40 or the dummy trench portion 30. The contact region 15 in the present example is in contact with the dummy trench portion 30 and the gate trench portion 40. The contact region 15 is also provided below the contact hole 54. A part of the contact region 15 exposed below the contact hole 54 may be provided with a high-concentration portion having a doping concentration higher than those of other parts.

The emitter region 12 and the contact region 15 may be repeatedly arrayed in the extending direction of the plurality of trench portions (the Y axis direction in the present example) in the mesa portion 71 adjacent to the gate trench portion 40. The emitter region 12 and the contact region 15 may be repeatedly arrayed in the extending direction of the plurality of trench portions even in the mesa portion 71 sandwiched between two dummy trench portions 30 adjacent to each other. The emitter region 12 and the contact region 15 in the present example are repeatedly arrayed in the extending direction of the plurality of trench portions in all the mesa portions 71 illustrated in the drawing.

The well region 17 is a region of the second conductivity type provided above the drift region 18. The well region 17 in the present example is of the P+ type as an example. A diffusion depth of the well region 17 may be deeper than the depth of the gate trench portion 40 and the dummy trench portion 30.

The trench bottom region 60 is a region of the second conductivity type which is provided below the gate trench portion 40 and has a doping concentration lower than that of the base region 14. The trench bottom region 60 in the present example is of the P−− type as an example. A doping concentration of the trench bottom region 60 may be 1% or more and 10% or less of a doping concentration of the base region 14. By providing the trench bottom region 60, a gate-collector capacitance can be increased, and dV/dt at a time of switching can be reduced. Accordingly, it possible to reduce a gate resistance in a design where dV/dt is set to a same value, thereby making it possible to increase dI/dt and to reduce a switching loss of the semiconductor device 100.

The trench bottom region 60 may be provided below the dummy trench portion 30, and may not be provided below the dummy trench portion 30. The trench bottom region 60 in the present example is also partially provided below the dummy trench portion 30.

When a collector-emitter voltage of the semiconductor device 100 increases, an electric field at a bottom portion of the gate trench portion 40 becomes strong, and avalanche breakdown may occur. When the avalanche breakdown occurs at the bottom portion of the gate trench portion 40, a charge generated by the avalanche breakdown is trapped in a gate dielectric film, and a threshold voltage Vth of the semiconductor device 100 may fluctuate. By providing the trench bottom region 60 below the gate trench portion 40 and partially providing the trench bottom region 60 below the dummy trench portion 30, avalanche breakdown can be caused to occur preferentially in a region of the bottom portion of the dummy trench portion 30 where the trench bottom region 60 is not formed. Accordingly, it is possible to suppress the occurrence of avalanche breakdown at the bottom portion of the gate trench portion 40 and to suppress the fluctuation of the threshold voltage Vth of the semiconductor device 100.

The trench bottom region 60 is provided below the emitter region 12. The trench bottom region 60 may or may not be provided below the contact region 15. The trench bottom region 60 in the present example is also provided below the contact region 15.

The semiconductor device 100 in the present example includes a trench bottom formation region 62 in which the trench bottom region 60 is formed in top view, and a trench bottom non-formation region 64 in which the trench bottom region 60 is not formed in top view. That is, a region other than the trench bottom formation region 62 where the trench bottom region 60 is formed in top view may be the trench bottom non-formation region 64. A boundary between the trench bottom formation region 62 and the trench bottom non-formation region 64 may be a boundary between the trench bottom region 60 and another region (for example, the drift region 18).

The trench bottom formation region 62 may cover the emitter region 12 provided in contact with the gate trench portion 40 in top view. The trench bottom formation region 62 in the present example is provided extending in the extending direction in the mesa portion 71 adjacent to the gate trench portion 40, and covers the emitter region 12 provided in contact with the gate trench portion 40 in top view. A channel is formed in the emitter region 12 provided in contact with the gate trench portion 40 during an operation of the semiconductor device 100. In top view, the trench bottom formation region 62 covers the emitter region 12 provided in contact with the gate trench portion 40, and the trench bottom region 60 is provided below the emitter region 12 provided in contact with the gate trench portion 40, whereby the occurrence of avalanche breakdown in a region where the channel is formed can be suppressed. Accordingly, it is possible to suppress the fluctuation of the threshold voltage Vth of the semiconductor device 100.

In top view, a distance L1 between an end side in the extending direction of the emitter region 12 provided on an outermost side in the extending direction and an end side in the extending direction of the trench bottom formation region 62 may be 1.0 μm or more and 10.0 μm or less. That is, the trench bottom formation region 62 provided extending in the extending direction may be provided so as to protrude by the distance L1 from the emitter region 12 provided on the outermost side in the extending direction. As described above, the trench bottom formation region 62 is provided so as to protrude from the emitter region 12, so that the trench bottom formation region 62 can reliably cover the emitter region 12. Accordingly, it is possible to suppress the occurrence of avalanche breakdown in the region where the channel is formed and to suppress the fluctuation of the threshold voltage Vth of the semiconductor device 100.

The plurality of trench portions in the present example have two adjacent dummy trench portions 30. The mesa portion 71 sandwiched between the two adjacent dummy trench portions 30 may be the trench bottom non-formation region 64.

The emitter region 12 in the present example is also provided in the mesa portion 71 sandwiched between the two adjacent dummy trench portions 30. The trench bottom non-formation region 64 may cover the emitter region 12 provided in the mesa portion 71 sandwiched between the two adjacent dummy trench portions 30 in top view. That is, the trench bottom region 60 may not be formed below the emitter region 12 which is provided in the mesa portion 71 sandwiched between the two adjacent dummy trench portions 30 and in which no channel is formed.

A length Wt in the array direction (the X axis direction in the present example) of the trench bottom region 60 is shorter than the length Wp of the repetitive structure included in the plurality of trench portions. That is, the trench bottom formation region 62 and the trench bottom non-formation region 64 may be provided during one cycle of the repetitive structure included in the plurality of trench portions. In this manner, the trench bottom formation region 62 may be provided so as to be surrounded by the trench bottom non-formation region 64.

When avalanche breakdown occurs at the bottom portion of the trench portion, a current filament may be generated due to positive feedback of the avalanche breakdown. As a result, a local temperature rise occurs, the avalanche breakdown is suppressed by the temperature rise, and the current filament moves. When a place where the current filament is generated is surrounded by the trench bottom formation region 62, the movement of the current filament is hindered, which may cause a further temperature rise and destroy the semiconductor device 100. In the semiconductor device 100 in the present example, since the trench bottom formation region 62 is provided to be surrounded by the trench bottom non-formation region 64, the movement of the current filament is not hindered, and destruction of the semiconductor device 100 can be suppressed.

FIG. 2B illustrates an example of a cross section a-a′ in FIG. 2A. The cross section a-a′ is an XZ plane passing through the emitter region 12 at the active portion 120. The semiconductor device 100 in the present example includes the semiconductor substrate 10, the interlayer dielectric film 38, the emitter electrode 52, and a collector electrode 24 in the cross section a-a′.

The drift region 18 is a region of the first conductivity type provided in the semiconductor substrate 10. The drift region 18 in the present example is of the N− type as an example. The drift region 18 may be a region which has remained without another doping region formed in the semiconductor substrate 10. That is, the doping concentration of the drift region 18 may be the doping concentration of the semiconductor substrate 10.

A buffer region 20 is a region of the first conductivity type which is provided on the back surface 23 side of the semiconductor substrate 10 with respect to the drift region 18. The buffer region 20 in the present example is of the N type as an example. The doping concentration of the buffer region 20 may be higher than the doping concentration of the drift region 18. The buffer region 20 may function as a field stop layer which prevents a depletion layer extending from a lower surface side of the base region 14 from reaching a collector region 22 of the second conductivity type. Note that the buffer region 20 may be omitted.

The collector region 22 is provided below the buffer region 20. The collector region 22 has the second conductivity type. The collector region 22 in the present example is of the P+ type as an example.

An accumulation region 16 is provided in contact with the gate trench portion 40. The accumulation region 16 may or may not be in contact with the dummy trench portion 30. The accumulation region 16 in the present example is in contact with the dummy trench portion 30. The accumulation region 16 in the present example is of the N+ type as an example. A doping concentration of the accumulation region 16 may be higher than the doping concentration of the drift region 18. A dose amount of ion implantation of the accumulation region 16 may be 1.0E+12 cm⁻² or more and 3.0E+13 cm⁻² or less. The accumulation region 16 being provided can enhance a carrier injection enhancement effect (IE effect) to decrease an ON voltage of the semiconductor device 100.

The base region 14 is provided in contact with the gate trench portion 40. The base region 14 may be provided in contact with the dummy trench portion 30. The emitter region 12 is provided between the base region 14 and the front surface 21.

One or more gate trench portions 40 and one or more dummy trench portions 30 are provided at the front surface 21. Each trench portion is provided from the front surface 21 to the drift region 18. In a region provided with at least one of the emitter region 12, the base region 14, the contact region 15, or the accumulation region 16, each trench portion also penetrates these regions to reach the drift region 18. The configuration of the trench portion penetrating each region is not limited to the one manufactured in the order of forming each region and then forming the trench portion. The configuration of the trench portion penetrating each region includes a configuration of each region being formed between the trench portions after forming the trench portion.

The gate trench portion 40 includes a gate trench formed at the front surface 21, a gate dielectric film 42, and a gate conductive portion 44. The gate dielectric film 42 is formed to cover an inner wall of the gate trench. The gate dielectric film 42 may be formed by oxidizing or nitriding a semiconductor on the inner wall of the gate trench. The gate conductive portion 44 is formed inside from the gate dielectric film 42 inside the gate trench. The gate dielectric film 42 insulates the gate conductive portion 44 from the semiconductor substrate 10. The gate conductive portion 44 is formed of a conductive material such as polysilicon. The gate trench portion 40 is covered with the interlayer dielectric film 38 on the front surface 21.

The gate conductive portion 44 includes a region opposing the adjacent base region 14 on a mesa portion 71 side with the gate dielectric film 42 interposed therebetween, in the depth direction of the semiconductor substrate 10. When a predetermined voltage is applied to the gate conductive portion 44, a channel is formed by an electron inversion layer in a surface layer of the base region 14 at an interface in contact with the gate trench.

The dummy trench portion 30 may have a same structure as that of the gate trench portion 40. The dummy trench portion 30 includes a dummy trench formed on the front surface 21 side, a dummy dielectric film 32, and a dummy conductive portion 34. The dummy dielectric film 32 is formed to cover an inner wall of the dummy trench. The dummy conductive portion 34 is formed inside the dummy trench, and is formed inside from the dummy dielectric film 32. The dummy dielectric film 32 insulates the dummy conductive portion 34 from the semiconductor substrate 10. The dummy trench portion 30 may be covered with the interlayer dielectric film 38 on the front surface 21.

The trench bottom region 60 may be in contact with the gate trench portion 40. When the trench bottom region 60 is in contact with the gate trench portion 40, it is possible to suppress the occurrence of avalanche breakdown at the bottom portion of the gate trench portion 40 and to suppress the fluctuation of the threshold voltage Vth of the semiconductor device 100.

The trench bottom region 60 may be in contact with the dummy trench portion 30 adjacent to the gate trench portion 40. When the trench bottom region 60 is in contact with the dummy trench portion 30, it is possible to fix a potential of the trench bottom region 60 to be equal to an emitter potential and to improve a switching loss reduction characteristic of the semiconductor device 100. Note that it is sufficient if the trench bottom region 60 is partially in contact with the dummy trench portion 30. When the trench bottom region 60 is partially in contact with the dummy trench portion 30, avalanche breakdown can be caused to occur preferentially in a region of the bottom portion of the dummy trench portion 30 where the trench bottom region 60 is not formed. Accordingly, it is possible to suppress the occurrence of avalanche breakdown at the bottom portion of the gate trench portion 40 and to suppress the fluctuation of the threshold voltage Vth of the semiconductor device 100.

The trench bottom region 60 may be formed by implanting ions of the second conductivity type into the bottom portion of the gate trench portion 40 and thermally diffusing the ions. That is, a concentration of the trench bottom region 60 may be high in a vicinity of the bottom portion of the gate trench portion 40 and may decrease as a distance from the bottom portion of the gate trench portion 40 increases. However, a method of forming the trench bottom region 60 is not limited to this. The trench bottom region 60 is formed by highly accelerated implantation of ions of the second conductivity type from the front surface 21 of the semiconductor substrate 10, and may have a substantially uniform concentration.

A back surface side lifetime control region 151 may be provided in the active portion 120. However, the back surface side lifetime control region 151 may be omitted. The back surface side lifetime control region 151 is a region where a lifetime killer has intentionally been formed by implanting impurities inside the semiconductor substrate 10, or the like. As an example, the back surface side lifetime control region 151 is formed by implanting helium into the semiconductor substrate 10. The back surface side lifetime control region 151 may also be formed by implanting protons. By providing the back surface side lifetime control region 151, a turn-off time can be reduced, and by suppressing a tail current, losses during switching can be reduced.

The lifetime killer is a recombination center of carriers. The lifetime killer may be a lattice defect. For example, the lifetime killer may be a vacancy, a divacancy, a defect complex of these with elements constituting the semiconductor substrate 10, or dislocation. In addition, the lifetime killer may be a noble gas element such as helium and neon, a metal element such as platinum, or the like. An electron beam or a proton may be used for forming the lattice defect.

A lifetime killer concentration is a concentration at the recombination center of carriers. The lifetime killer concentration may be a concentration of the lattice defect. For example, the lifetime killer concentration may be a vacancy concentration of a vacancy, a divacancy, or the like, may be a defect complex concentration of these vacancies with elements constituting the semiconductor substrate 10, or may be a dislocation concentration. In addition, the lifetime killer concentration may be a chemical concentration of the noble gas element such as helium and neon, or may be a chemical concentration of the metal element such as platinum.

The back surface side lifetime control region 151 is provided on the back surface 23 side with respect to the center of the drift region 18 in the depth direction of the semiconductor substrate 10. The back surface side lifetime control region 151 of the present example is provided in the buffer region 20. The back surface side lifetime control region 151 of the present example is provided on an entire surface of the semiconductor substrate 10 in the XY plane, and can be formed without using a mask. The back surface side lifetime control region 151 may be provided in a part of the semiconductor substrate 10 in the XY plane. An impurity dose amount for forming the back surface side lifetime control region 151 may be 0.5E+10 cm⁻² or more and 1.0E+14 cm⁻² or less, or may be 5.0E+10 cm⁻² or more and 1.0E+13 cm⁻² or less.

The back surface side lifetime control region 151 may be formed by implantation from the back surface 23 side. Accordingly, it becomes easy to avoid an effect on the front surface 21 side of the semiconductor device 100. For example, the back surface side lifetime control region 151 is formed by irradiating helium or a proton from the back surface 23 side. Herein, which of the front surface 21 side and the back surface 23 side the implantation is performed from for forming the back surface side lifetime control region 151 can be determined by acquiring a state of the front surface 21 side by an SR method or measurement of a leakage current.

The interlayer dielectric film 38 is provided above the semiconductor substrate 10. The interlayer dielectric film 38 in the present example is provided in contact with the front surface 21. The emitter electrode 52 is provided above the interlayer dielectric film 38. The interlayer dielectric film 38 is provided with one or more contact holes 54 for electrically connecting the emitter electrode 52 to the semiconductor substrate 10. A film thickness of the interlayer dielectric film 38 is, for example, 1.0 μm, but it is not limited to this.

The interlayer dielectric film 38 may be a silicon oxide film. The interlayer dielectric film 38 may be a boro-phospho silicate glass (BPSG) film, may be a borosilicate glass (BSG) film, or may be a phosphosilicate glass (PSG) film. The interlayer dielectric film 38 may also include a high temperature silicon oxide (HTO: High Temperature Oxide) film.

The collector electrode 24 is formed on the back surface 23 of the semiconductor substrate 10. The collector electrode 24 is formed of a conductive material such as metal. At least a partial region of the collector electrode 24 may be formed of metal such as aluminum (Al) or a metal alloy such as an aluminum-silicon alloy (AlSi) or an aluminum-silicon-copper alloy (AlSiCu). The collector electrode 24 may have a barrier metal formed of titanium, a titanium compound, or the like on the semiconductor substrate 10 side with respect to a region formed of aluminum or the like.

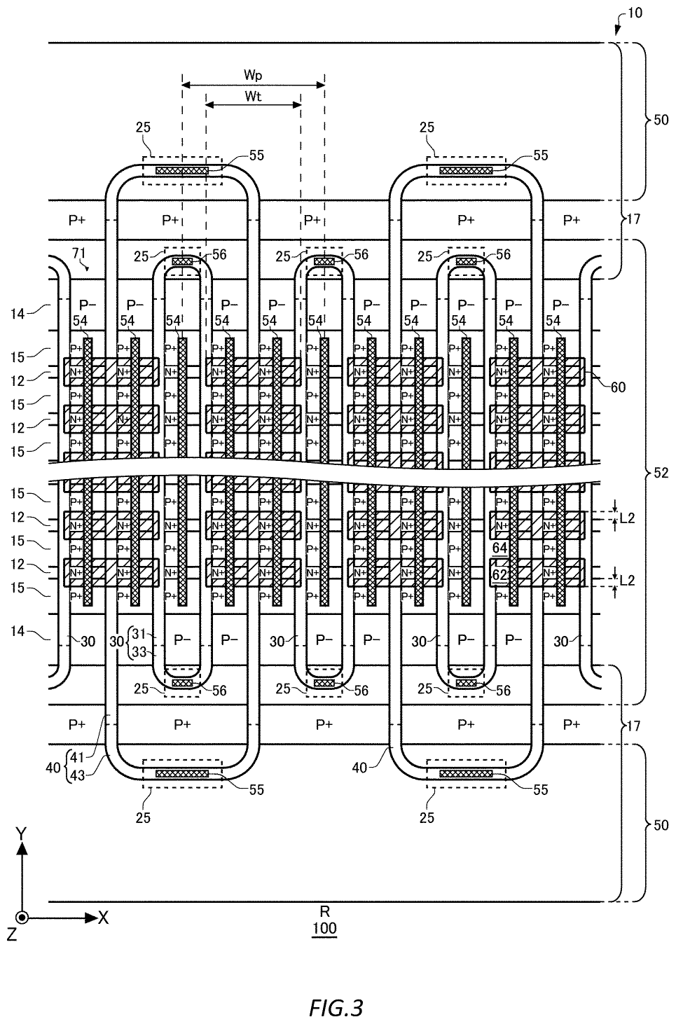

FIG. 3 illustrates the region R in a modification of the semiconductor device 100. The semiconductor device 100 in the present example is different from the example of FIG. 2A in that the trench bottom formation region 62 and the trench bottom non-formation region 64 are repeatedly arrayed in the extending direction in the mesa portion 71 adjacent to the gate trench portion 40. In the present example, the difference from the example of FIG. 2A will be particularly described, and other configurations may be the same as those in the example of FIG. 2A.

The emitter region 12 and the contact region 15 may be repeatedly arrayed in the extending direction of the plurality of trench portions (the Y axis direction in the present example) in the mesa portion 71 adjacent to the gate trench portion 40. The trench bottom formation region 62 and the trench bottom non-formation region 64 may be repeatedly arrayed in the extending direction in the mesa portion 71 adjacent to the gate trench portion 40. The repeatedly arrayed trench bottom formation region 62 may cover the repeatedly arrayed emitter region 12 in top view. That is, the end portion in the Y axis direction of the trench bottom region 60 may be located below the contact region 15. Since the trench bottom formation region 62 covers the emitter region 12 in top view, it is possible to suppress the occurrence of avalanche breakdown in a region where a channel is formed and to suppress the fluctuation of the threshold voltage Vth of the semiconductor device 100.

In top view, a distance L2 between the end side in the extending direction of the emitter region 12 and the end side in the extending direction of the trench bottom formation region 62 covering the emitter region 12 may be 1.0 μm or more and 2.5 μm or less. That is, the trench bottom formation region 62 repeatedly arrayed in the extending direction may be provided so as to protrude by the distance L2 from the emitter region 12 covered by the trench bottom formation region 62. As described above, the trench bottom formation region 62 is provided so as to protrude from the emitter region 12, so that the trench bottom formation region 62 can reliably cover the emitter region 12. Accordingly, it is possible to suppress the occurrence of avalanche breakdown in the region where the channel is formed and to suppress the fluctuation of the threshold voltage Vth of the semiconductor device 100.

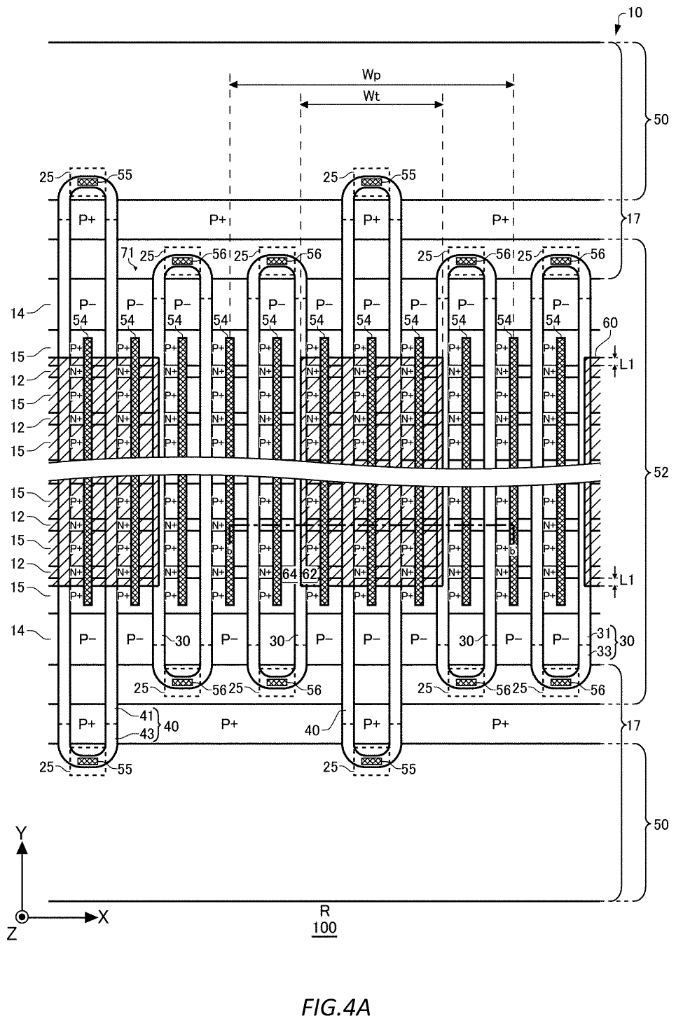

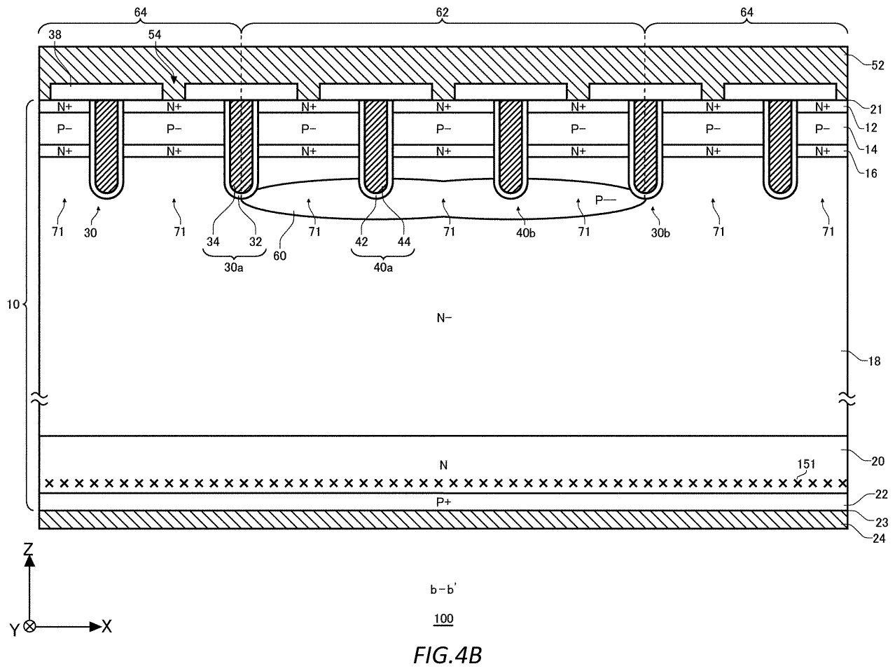

FIG. 4A illustrates the region R in a modification of the semiconductor device 100. The semiconductor device 100 in the present example is different from the example of FIG. 2A in that the repetitive structure included in the plurality of trench portions is different. In the present example, the difference from the example of FIG. 2A will be particularly described, and other configurations may be the same as those in the example of FIG. 2A.

The plurality of trench portions in the present example has a repetitive structure in which the dummy trench portion 30, the dummy trench portion 30, the gate trench portion 40, the gate trench portion 40, the dummy trench portion 30, and the dummy trench portion 30 are repeated in this order in the array direction (the X axis direction in the present example). That is, the semiconductor device 100 in the present example includes the gate trench portions 40 and the dummy trench portions 30 at a ratio of 2:4.

The contact hole 54 in the present example is also provided in the mesa portion 71 sandwiched between two gate trench portions 40. The contact hole 54 may not be provided in the mesa portion 71 sandwiched between the two gate trench portions 40. When the contact hole 54 is not provided in the mesa portion 71 sandwiched between the two gate trench portions 40, the mesa portion 71 may be a floating region.

The emitter region 12 in the present example is also provided in the mesa portion 71 sandwiched between two gate trench portions 40. The emitter region 12 may not be provided in the mesa portion 71 sandwiched between the two gate trench portions 40.

FIG. 4B illustrates an example of a cross section b-b′ in FIG. 4A. The cross section b-b′ is an XZ plane passing through the emitter region 12 at the active portion 120. In the present example, the difference from the example of FIG. 2B will be particularly described, and other configurations may be the same as those in the example of FIG. 2B.

The trench bottom region 60 may be in contact with the dummy trench portion 30 adjacent to the gate trench portion 40, and may not be in contact with the dummy trench portion 30 not adjacent to the gate trench portion 40. That is, the semiconductor device 100 may have the dummy trench portion 30 in which the trench bottom region 60 is not formed at the bottom portion. Accordingly, it is possible to cause avalanche breakdown to occur preferentially in the dummy trench portion 30 in which the trench bottom region 60 is not formed at the bottom portion, and it is possible to suppress the occurrence of avalanche breakdown at the bottom portion of the gate trench portion 40 and to suppress the fluctuation of the threshold voltage Vth of the semiconductor device 100.

The trench bottom region 60 in the present example is integrally provided from a dummy trench portion 30a adjacent to one gate trench portion 40a of two adjacent gate trench portions 40 to a dummy trench portion 30b adjacent to another gate trench portion 40b. That is, the trench bottom region 60 may be integrally provided by overlapping a region where ions of the second conductivity type implanted into a bottom portion of the gate trench portion 40a are thermally diffused and a region where ions of the second conductivity type implanted into a bottom portion of the gate trench portion 40b are thermally diffused. However, when the two adjacent gate trench portions 40 are provided spaced apart by a diffusion length of ions of the second conductivity type or more, the trench bottom region 60 may be formed at the bottom portion of each gate trench portion 40.

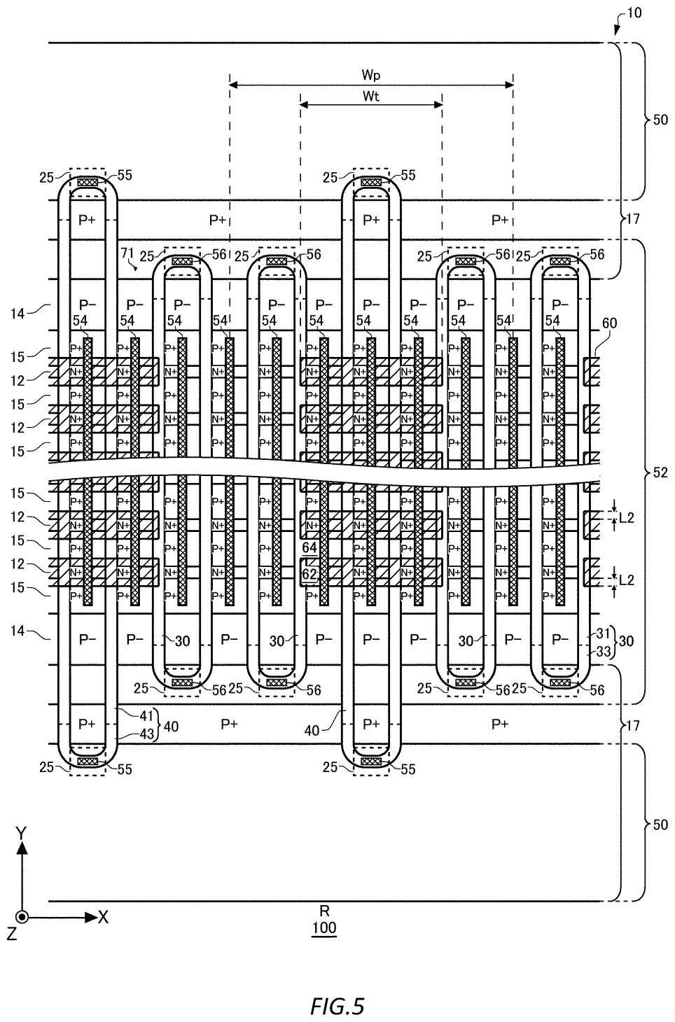

FIG. 5 illustrates the region R in a modification of the semiconductor device 100. The semiconductor device 100 in the present example is different from the example of FIG. 4A in that the trench bottom formation region 62 and the trench bottom non-formation region 64 are repeatedly arrayed in the extending direction in the mesa portion 71 adjacent to the gate trench portion 40. Other configurations may be the same as those in the example of FIG. 4A. In addition, the trench bottom formation regions 62 and trench bottom non-formation regions 64 which are repeatedly arrayed may be the same as those in the example of FIG. 3.

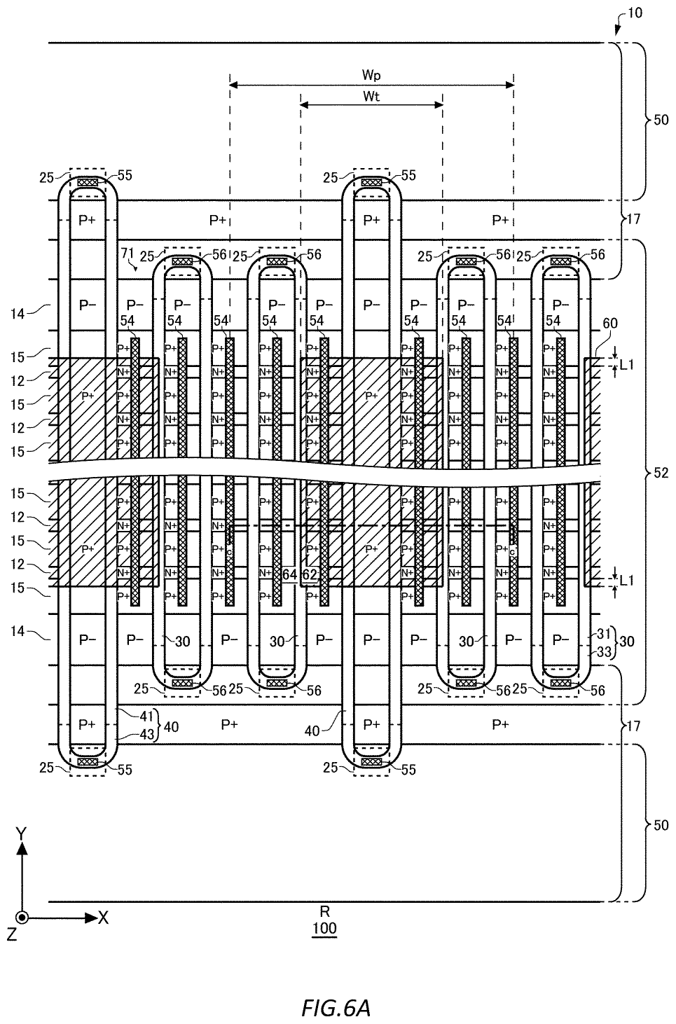

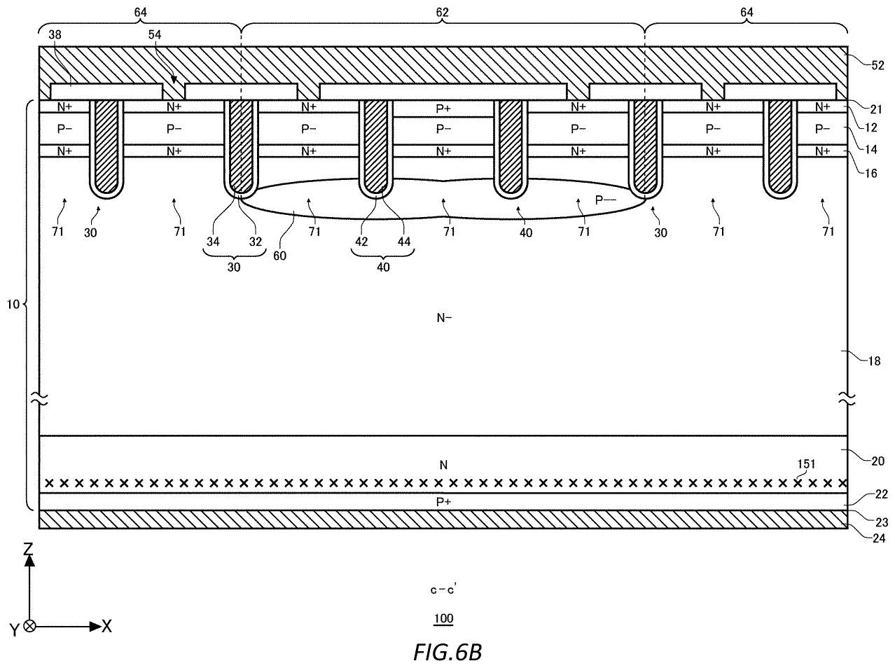

FIG. 6A illustrates the region R in a modification of the semiconductor device 100. The semiconductor device 100 in the present example is different from the example of FIG. 4A in that the emitter region 12 and the contact hole 54 are not provided in the mesa portion 71 sandwiched between two gate trench portions 40. In the present example, the difference from the example of FIG. 4A will be particularly described, and other configurations may be the same as those in the example of FIG. 4A.

The mesa portion 71 sandwiched between two adjacent gate trench portions 40 in the present example is not provided with the contact hole 54. Therefore, the mesa portion 71 sandwiched between the two adjacent gate trench portions 40 in the present example is a floating region. However, the contact hole 54 is provided in the mesa portion 71 sandwiched between the two adjacent gate trench portions 40, and the mesa portion 71 is connected to the emitter electrode 52 via the contact hole 54, whereby the mesa portion 71 may have a hole extraction function. In addition, as illustrated in FIG. 4A, the emitter region 12 and the contact hole 54 may be provided to function as a region where a channel is formed.

FIG. 6B illustrates an example of a cross section c-c′ in FIG. 6A. The cross section c-c′ is an XZ plane passing through the emitter region 12 at the active portion 120. In the present example, the difference from the example of FIG. 4B will be particularly described, and other configurations may be the same as those in the example of FIG. 4B.

The trench bottom region 60 in the present example is also provided below the mesa portion 71 sandwiched between the two adjacent gate trench portions 40 where the emitter region 12 is not provided. When the two adjacent gate trench portions 40 are provided spaced apart by the diffusion length of ions of the second conductivity type or more, the trench bottom region 60 may not be provided below the mesa portion 71 sandwiched between the two adjacent gate trench portions 40. That is, since the emitter region 12 is not provided in the mesa portion 71 sandwiched between the two adjacent gate trench portions 40 in the present example, and no channel is formed during the operation of the semiconductor device 100, the trench bottom region 60 may not be provided below the mesa portion 71.

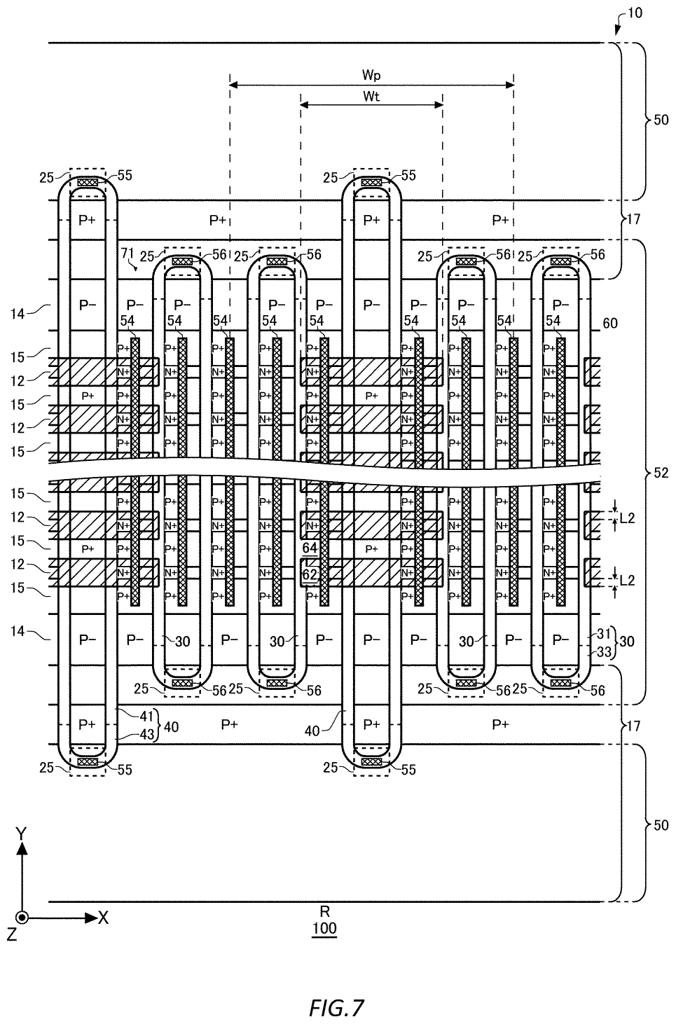

FIG. 7 illustrates the region R in a modification of the semiconductor device 100. The semiconductor device 100 in the present example is different from the example of FIG. 6A in that the trench bottom formation region 62 and the trench bottom non-formation region 64 are repeatedly arrayed in the extending direction in the mesa portion 71 adjacent to the gate trench portion 40. Other configurations may be the same as those in the example of FIG. 6A. In addition, the trench bottom formation regions 62 and trench bottom non-formation regions 64 which are repeatedly arrayed may be the same as those in the examples of FIGS. 3 and 5.

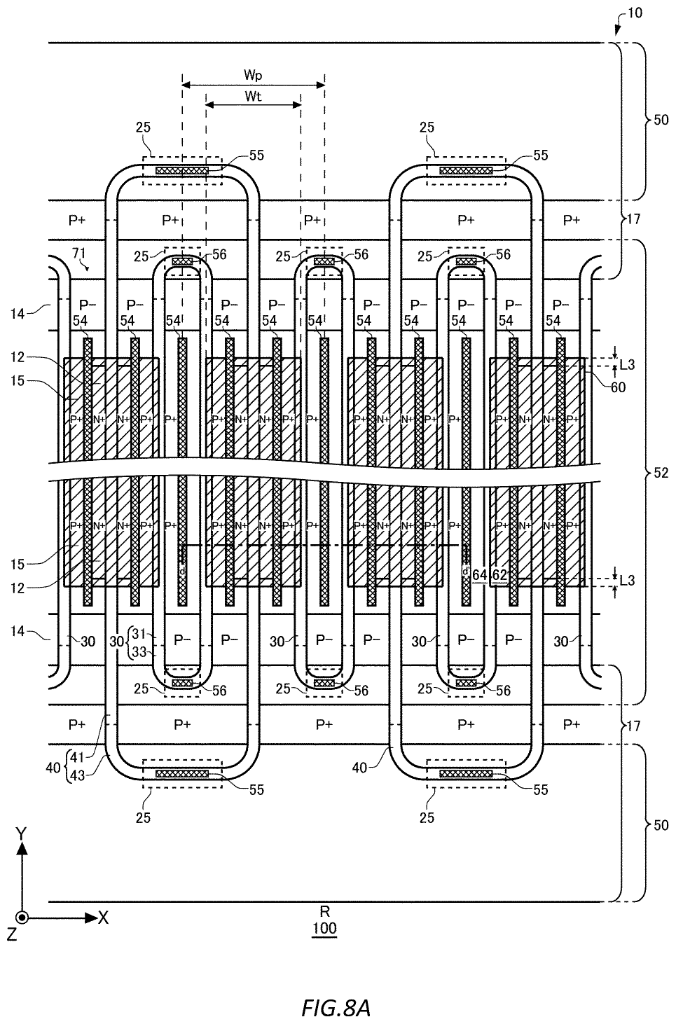

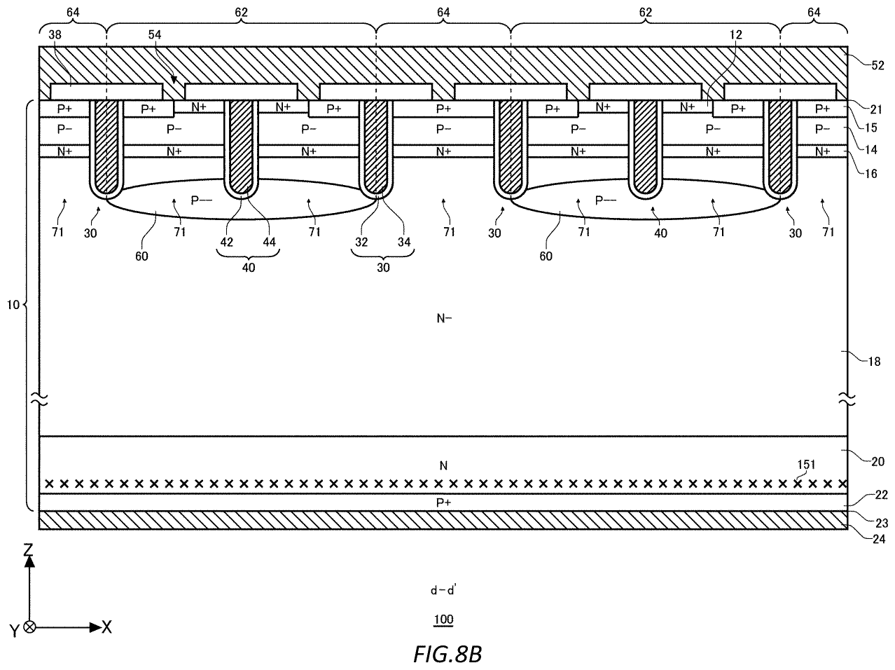

FIG. 8A illustrates the region R in a modification of the semiconductor device 100. The semiconductor device 100 in the present example is different from the example of FIG. 2A in that the emitter region 12 is provided extending in the extending direction. In the present example, the difference from the example of FIG. 2A will be particularly described, and other configurations may be the same as those in the example of FIG. 2A.

In the mesa portion 71 adjacent to the gate trench portion 40, the emitter region 12 may be provided in contact with the gate trench portion 40, not in contact with the dummy trench portion 30, and extending in the extending direction of the plurality of trench portions (the Y axis direction in the present example). The trench bottom formation region 62 may be provided extending in the extending direction in the mesa portion 71 adjacent to the gate trench portion 40, and cover the emitter region 12 provided in contact with the gate trench portion 40 in top view. Since the trench bottom formation region 62 covers the emitter region 12 in top view, it is possible to suppress the occurrence of avalanche breakdown in a region where a channel is formed and to suppress the fluctuation of the threshold voltage Vth of the semiconductor device 100.

In top view, a distance L3 between the end side in the extending direction of the emitter region 12 and the end side in the extending direction of the trench bottom formation region 62 covering the emitter region 12 may be 1.0 μm or more and 5.0 μm or less. That is, the trench bottom formation region 62 provided extending in the extending direction may be provided so as to protrude by the distance L3 from the emitter region 12 provided extending in the extending direction. As described above, the trench bottom formation region 62 is provided so as to protrude from the emitter region 12, so that the trench bottom formation region 62 can reliably cover the emitter region 12. Accordingly, it is possible to suppress the occurrence of avalanche breakdown in the region where the channel is formed and to suppress the fluctuation of the threshold voltage Vth of the semiconductor device 100.

FIG. 8B illustrates an example of a cross section d-d′ in FIG. 8A. The cross section d-d′ is an XZ plane passing through the emitter region 12 at the active portion 120. In the present example, the difference from the example of FIG. 2B will be particularly described, and other configurations may be the same as those in the example of FIG. 2B.

In the mesa portion 71 adjacent to the gate trench portion 40, the contact hole 54 may be provided above the emitter region 12 and the contact region 15. That is, a boundary between the emitter region 12 and the contact region 15 may be located below the contact hole 54.

While the present invention has been described by way of the embodiments, the technical scope of the present invention is not limited to the above-described embodiments. It is apparent to persons skilled in the art that various alterations or improvements can be made to the above described embodiments. It is also apparent from description of the claims that the embodiments to which such changes or improvements are made may be included in the technical scope of the present invention.

It should be noted that each process of the operations, procedures, steps, stages, and the like performed by the device, system, program, and method shown in the claims, specification, or drawings can be executed in any order as long as the order is not indicated by “prior to”, “before”, or the like and as long as the output from a previous process is not used in a later process. Even if the operation flow is described using phrases such as “first” or “next” for the sake of convenience in the claims, specification, or drawings, it does not necessarily mean that the process must be performed in this order.

### EXPLANATION OF REFERENCES

10: semiconductor substrate; 12: emitter region; 14: base region; 15: contact region; 16: accumulation region; 17: well region; 18: drift region; 20: buffer region; 21: front surface; 22: collector region; 23: back surface; 24: collector electrode; 25: connection portion; 30: dummy trench portion; 31: extending part; 32: dummy dielectric film; 33: connecting part; 34: dummy conductive portion; 38: interlayer dielectric film; 40: gate trench portion; 41: extending part; 42: gate dielectric film; 43: connecting part; 44: gate conductive portion; 50: gate runner portion; 52: emitter electrode; 54: contact hole; 55: contact hole; 56: contact hole; 60: trench bottom region; 62: trench bottom formation region; 64: trench bottom non-formation region; 71: mesa portion; 100: semiconductor device; 102: end side; 112: gate pad; 120: active region; 140: edge termination structure portion; and 151: back surface side lifetime control region.

What is claimed is:

1. A semiconductor device comprising:
a plurality of trench portions which are arrayed in an array direction which is predetermined on a front surface side of a semiconductor substrate and has a repetitive structure in which a gate trench portion and a dummy trench portion are repeated at a predetermined cycle in the array direction;
a drift region of a first conductivity type which is provided in the semiconductor substrate;
a base region of a second conductivity type which is provided above the drift region;
an emitter region of the first conductivity type which is provided above the base region and has a doping concentration higher than that of the drift region;
a contact region of the second conductivity type which is provided above the base region and has a doping concentration higher than that of the base region; and
a trench bottom region of the second conductivity type which is provided below the gate trench portion and has a doping concentration lower than that of the base region, wherein
the trench bottom region is provided below the emitter region, and
a length in the array direction of the trench bottom region is shorter than a length of the repetitive structure.

2. The semiconductor device according to claim 1, wherein
the trench bottom region is in contact with the gate trench portion.

3. The semiconductor device according to claim 2, wherein
the trench bottom region is in contact with the dummy trench portion adjacent to the gate trench portion.

4. The semiconductor device according to claim 1, comprising
a trench bottom formation region where the trench bottom region is formed in top view; and
a trench bottom non-formation region where the trench bottom region is not formed in top view.

5. The semiconductor device according to claim 4, wherein
the trench bottom formation region covers the emitter region provided in contact with the gate trench portion in top view.

6. The semiconductor device according to claim 4, wherein
the emitter region and the contact region are repeatedly arrayed in an extending direction of the plurality of trench portions in a mesa portion adjacent to the gate trench portion, and
the trench bottom formation region is provided extending in the extending direction in a mesa portion adjacent to the gate trench portion, and covers the emitter region provided in contact with the gate trench portion in top view.

7. The semiconductor device according to claim 6, wherein
in top view, a distance between an end side in the extending direction of the emitter region provided on an outermost side in the extending direction and an end side in the extending direction of the trench bottom formation region is 1.0 μm or more and 10.0 μm or less.

8. The semiconductor device according to claim 4, wherein
in a mesa portion adjacent to the gate trench portion, the emitter region is provided in contact with the gate trench portion, not in contact with the dummy trench portion, and extending in an extending direction of the plurality of trench portions, and
the trench bottom formation region is provided extending in the extending direction in a mesa portion adjacent to the gate trench portion, and covers the emitter region provided in contact with the gate trench portion in top view.

9. The semiconductor device according to claim 8, wherein
in top view, a distance between an end side in the extending direction of the emitter region and an end side in the extending direction of the trench bottom formation region covering the emitter region is 1.0 μm or more and 5.0 μm or less.

10. The semiconductor device according to claim 4, wherein
the emitter region and the contact region are repeatedly arrayed in an extending direction of the plurality of trench portions in a mesa portion adjacent to the gate trench portion,
the trench bottom formation region and the trench bottom non-formation region are repeatedly arrayed in the extending direction in a mesa portion adjacent to the gate trench portion, and
in top view, the trench bottom formation region which is repeatedly arrayed covers the emitter region which is repeatedly arrayed.

11. The semiconductor device according to claim 10, wherein
in top view, a distance between an end side in the extending direction of the emitter region and an end side in the extending direction of the trench bottom formation region covering the emitter region is 1.0 μm or more and 2.5 μm or less.

12. The semiconductor device according to claim 4, wherein
the plurality of trench portions include two dummy trench portions adjacent to each other, and
a mesa portion sandwiched between the two dummy trench portions is the trench bottom non-formation region.

13. The semiconductor device according to claim 12, wherein
the emitter region is also provided in the mesa portion sandwiched between the two dummy trench portions, and
in top view, the trench bottom non-formation region covers the emitter region provided in the mesa portion sandwiched between the two dummy trench portions.

14. The semiconductor device according to claim 1, wherein
the plurality of trench portions have the repetitive structure in which the dummy trench portion, the gate trench portion, and the dummy trench portion are repeated in this order in the array direction.

15. The semiconductor device according to claim 2, wherein
the plurality of trench portions have the repetitive structure in which the dummy trench portion, the gate trench portion, and the dummy trench portion are repeated in this order in the array direction.

16. The semiconductor device according to claim 3, wherein
the plurality of trench portions have the repetitive structure in which the dummy trench portion, the gate trench portion, and the dummy trench portion are repeated in this order in the array direction.

17. The semiconductor device according to claim 1, wherein
the plurality of trench portions have the repetitive structure in which the dummy trench portion, the dummy trench portion, the gate trench portion, the gate trench portion, the dummy trench portion, and the dummy trench portion are repeated in this order in the array direction.

18. The semiconductor device according to claim 2, wherein
the plurality of trench portions have the repetitive structure in which the dummy trench portion, the dummy trench portion, the gate trench portion, the gate trench portion, the dummy trench portion, and the dummy trench portion are repeated in this order in the array direction.

19. The semiconductor device according to claim 1, wherein
a doping concentration of the trench bottom region is 1% or more and 10% or less of a doping concentration of the base region.

20. The semiconductor device according to claim 2, wherein
a doping concentration of the trench bottom region is 1% or more and 10% or less of a doping concentration of the base region.
